(19) United States
(12) Patent Application Publication
(10) Pub. No.: US 2019/0081192 A1
(43) Pub. Date: Mar. 14, 2019

(54) SOLAR-BLIND DETECTING DEVICE WITH WIDE-BANDGAP OXIDE

(71) Applicants: TYNTEK CORPORATION, Hsinchu City (TW); NATIONAL CHIAO TUNG UNIVERSITY, Hsinchu (TW)

(72) Inventors: RAY-HUA HORNG, HSINCHU (TW); YEN-CHU LI, MIAOLI COUNTY (TW); CHUN-YI TUNG, MIAOLI COUNTY (TW); SI-HAN TSAI, HSINCHU (TW); LI-CHUNG CHENG, HSINCHU (TW)

(21) Appl. No.: 15/878,788

(22) Filed: Jan. 24, 2018

(30) Foreign Application Priority Data
Sep. 12, 2017 (TW) 106131302

(51) Int. Cl. H01L 31/032; H01L 31/108

(52) U.S. Cl. CPC H01L 31/0322; H01L 31/1085

(57) ABSTRACT

The present invention provides a solar-blind detecting device with a wide-bandgap oxide, which comprises an oxide epitaxial sensing layer disposed on a substrate for improving the property as well as substantially increasing the photocurrent in the oxide epitaxial sensing layer under the stimulation of ultraviolet light. Particularly, the sensing performance for the deep ultraviolet region (200˜280 nanometers) is enhanced significantly.

### FIELD OF THE INVENTION

The present invention relates generally to a sensing device, and particularly to a solar-blind sensing device with a wide-bandgap oxide.

### BACKGROUND OF THE INVENTION

As technologies progress day by day, various micro processes and fabrication technologies are developing rapidly and thus enabling various high-tech devices are developing toward the trend of preciseness and miniaturization. The applications of the miniature devices are extensive, including military, industrial, medical, optoelectronic communication, biotechnological, and daily applications. Mobile phones, ink injecting devices in printers, biochips, and various optical communication devices are examples. Due to people's urgent demand in miniature materials, the era has progressed from micrometer (10⁻⁶) range to nanometer (10⁻⁹) range.

In the semiconductor fabrication process according to the prior art, masks are adopted for patterning wafers and semiconductor substrates and forming various semiconductor devices. As the technologies for integrated circuits advance, product miniaturization is made possible, and the density of circuit layout and feature line in semiconductor devices become finer.

Currently, the sterilizing capability of ultraviolet light has been verified. The deep ultraviolet (DUV) light with wavelengths between 200 and 280 nanometers can destroy the bonds of DNA and RNA in bacteria and viruses. The sterilization efficiency can reach 99% to 99.9%. Particularly, the sterilization effect is best for wavelengths between 250 and 270 nanometers.

In recent years, no matter in the academics or industry, based on the outstanding research in the optoelectronic material of aluminum gallium nitride (AlGaN), the developed DUV photodetectors are found to be applicable to biochemical detection, disinfection, sterilization, or military applications. For the devices of the series, AlGaN epitaxial layers with high aluminum ratio are needed. Unfortunately, as the doping ratio of aluminum is increased, the crystal quality will deteriorate. In addition, compared to gallium nitride, the doping efficiency of n-type AlGaN epitaxial layers is lower, making the formation of ohmic contacts in n-type high-aluminum-ration AlGaN epitaxial layers difficult. For DUV sensors, the production yield is lowered as well.

To sum up, the present invention provides a solar-blind sensing device with a doping structure for overcoming the above technical shortcomings. It provides a novel wide-bandgap oxide, leading to superior optoelectronic performance in nanometer fabrication environments.

### SUMMARY

An objective of the present invention is to provide a solar-blind sensing device with a wide-bandgap oxide, which comprises an oxide epitaxial sensing layer for providing superior DUV sensing efficiency.

To achieve the above objective, the present invention provides a solar-blind sensing device with a wide-bandgap oxide, which comprises a substrate, an oxide epitaxial sensing layer, and a circuit layer. The oxide epitaxial sensing layer is disposed on the substrate and is a single-crystal compound thin film containing gallium and zinc. The circuit layer is disposed on the oxide epitaxial sensing layer and includes a first circuit unit and a second circuit unit. The first circuit unit is located on a first side of the circuit layer; the second circuit unit is located on a second side of the circuit layer. The first circuit unit includes a plurality of first extending parts; the second circuit unit includes a plurality of second extending parts. The plurality of first extending parts and the plurality of second extending parts are interlaced and extend on the oxide epitaxial sensing layer. In addition, when a ray of incident light is incident to the oxide epitaxial sensing layer, the oxide epitaxial sensing layer will generate a photocurrent in the circuit layer. According to the present invention, various ratios of zinc and gallium are introduced into the oxide epitaxial sensing layer for providing superior sensing performance DUV light.

According to an embodiment of the present invention, the oxide epitaxial sensing layer is a single-crystalline thin film.

According to an embodiment of the present invention, the flow rate of zinc for growth is between 5 and 20 sccm for producing epitaxial films with various zinc ratios.

According to an embodiment of the present invention, a continuously extending snake-shaped groove is located between the plurality of first extending parts and the plurality of second extending parts.

According to an embodiment of the present invention, the incident angles of X-ray diffraction to the oxide epitaxial sensing layer include 18.67, 37.77, and 58.17 degrees.

According to an embodiment of the present invention, the substrate is a sapphire substrate.

According to an embodiment of the present invention, the oxide epitaxial sensing layer is annealed between 800 and 950 degrees Celsius in nitrogen or oxygen ambient.

According to an embodiment of the present invention, the sensing wavelength of the oxide epitaxial sensing layer is between 150 and 280 nanometers.

To sum up, the present invention provides a solar-blind sensing device with a wide-bandgap oxide. The wide bandgap of the oxide epitaxial sensing layer provides superior sensing performance.

### BRIEF DESCRIPTION OF THE DRAWINGS

FIG. 1A shows a schematic diagram according to an embodiment of the present invention;

FIG. 1B shows a schematic diagram of light illumination according to an embodiment of the present invention;

FIG. 2 shows a schematic diagram of the lattice according to an embodiment of the present invention;

FIG. 3 shows curves of photocurrents versus wavelengths according to an embodiment of the present invention.

FIG. 4 shows a schematic diagram of annealing according to another embodiment of the present invention;

FIG. 5 shows a schematic diagram of the lattice according to another embodiment of the present invention;

FIG. 6 shows curves of annealing versus wavelengths according to another embodiment of the present invention; and

FIG. 7 shows curves of annealing versus reaction time according to an embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

In the specifications and subsequent claims, certain words are used for representing specific devices. A person having ordinary skill in the art should know that hardware manufacturers might use different nouns to call the same device. In the specifications and subsequent claims, the differences in names are not used for distinguishing devices. Instead, the differences in functions are the guidelines for distinguishing. In the whole specifications and subsequent claims, the word “comprising” is an open language and should be explained as “comprising but not limited to”. Besides, the word “couple” includes any direct and indirect electrical connection. Thereby, if the description is that a first device is coupled to a second device, it means that the first device is connected electrically to the second device directly, or the first device is connected electrically to the second device via other device or connecting means indirectly.

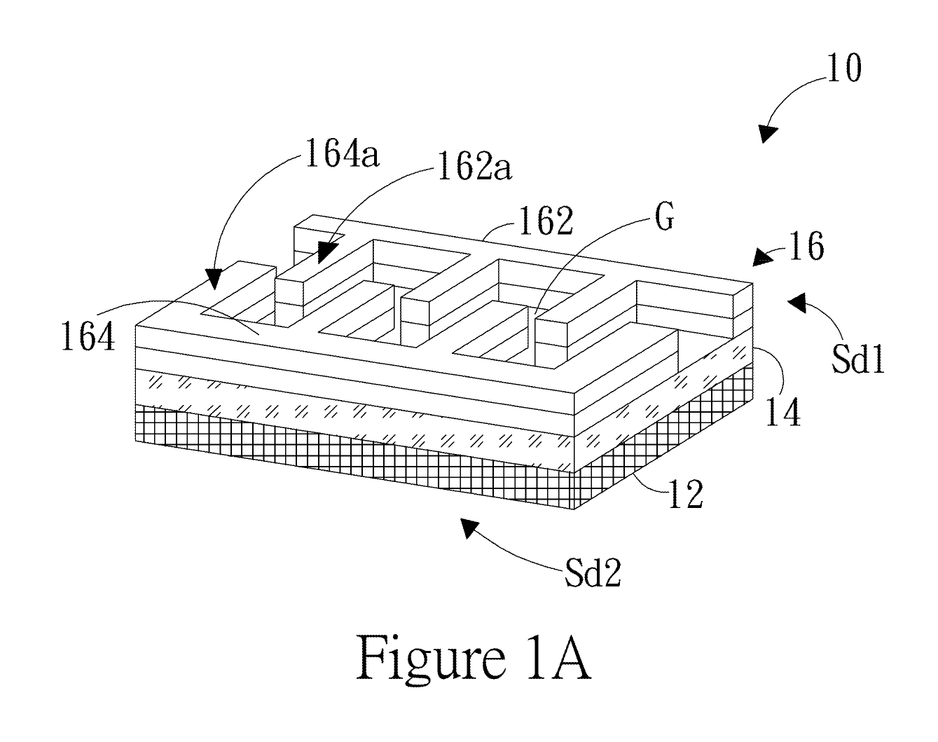

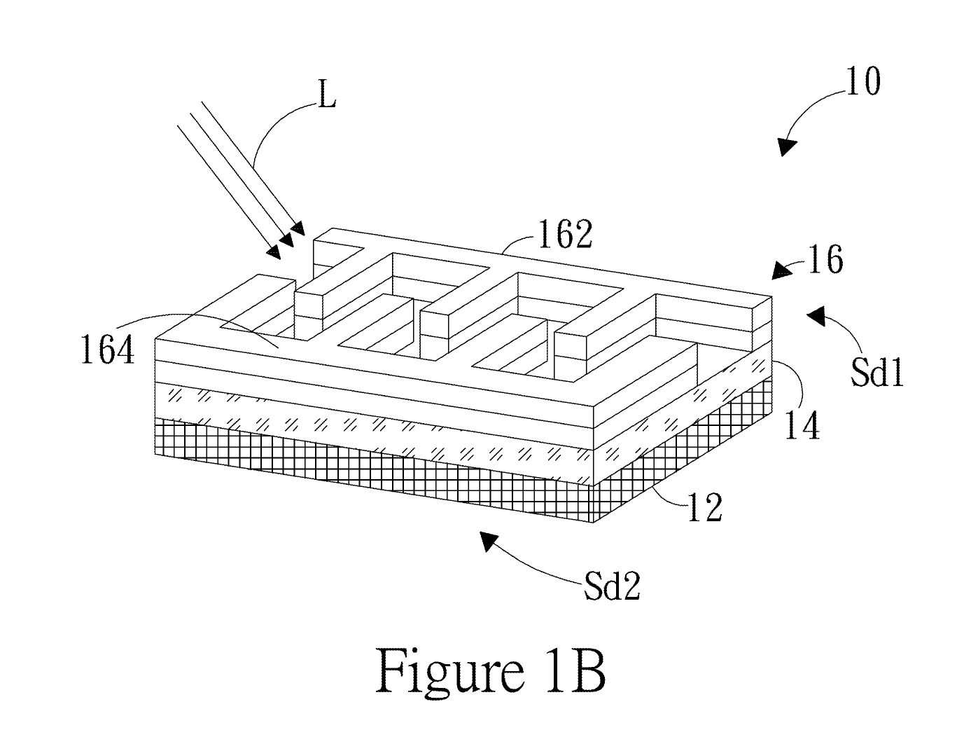

First, please refer to FIG. 1A, which shows a schematic diagram according to an embodiment of the present invention. As shown in the figure, the present invention provides a solar-blind detecting device with a wide-bandgap oxide 10, which comprises a substrate 12, an oxide epitaxial sensing layer 14, and a circuit layer 16. The circuit layer 16 includes a first circuit unit 162 and a second circuit unit 164. The first circuit unit 162 includes a plurality of first extending parts 162a; the second circuit unit 164 includes a plurality of second extending parts 164a. In addition, the solar-blind sensing device 10 has a first side Sd1 and a second side Sd2. The oxide epitaxial sensing layer 14 is disposed on the substrate 12; the circuit layer 16 is disposed on the oxide epitaxial sensing layer 14. Furthermore, the first circuit unit 162 is located on the first side Sd1 and disposed on the oxide epitaxial sensing layer 14; the second circuit unit 164 is located on the second side Sd2 and located on the oxide epitaxial sensing layer 14. The substrate 12 is a sapphire substrate. The oxide epitaxial sensing layer 14 is an epitaxial film grown by aerating zinc-containing gas at flow rates between 5 and 20 sccm (standard-state cubic centimeter per minute) for doping various zinc ratios. Besides, the material of the circuit layer 16 is selected from the group consisting of titanium, aluminum, and gold.

In addition, the plurality of first extending parts 162a extend from the first circuit unit 162, namely, from the first side Sd1, to the second circuit unit 164, namely, to the second side Sd2; the plurality of second extending parts 164a extend from the second unit 164, namely, from the second Sd2, to the first circuit unit 162, namely, to the first Sd1. The plurality of first extending parts 162a and the plurality of second extending parts 164a are interlaced and extend. Thereby, a continuously extending snake-shaped groove G is located between the plurality of first extending parts 162a and the plurality of second extending parts 164a. Besides, as shown in FIG. 1B, the first circuit unit 162 of the second circuit unit 164 of the circuit layer 16 are connected electrically to an external circuit (not shown in the figure), respectively. Hence, when the oxide epitaxial sensing layer 14 receives the incident light L, electrons ad holes change from the second circuit unit 164 via the oxide epitaxial sensing layer 14 to the first circuit unit 162, resulting in a photocurrent between the first and second circuit units 162, 164 to the external circuit.

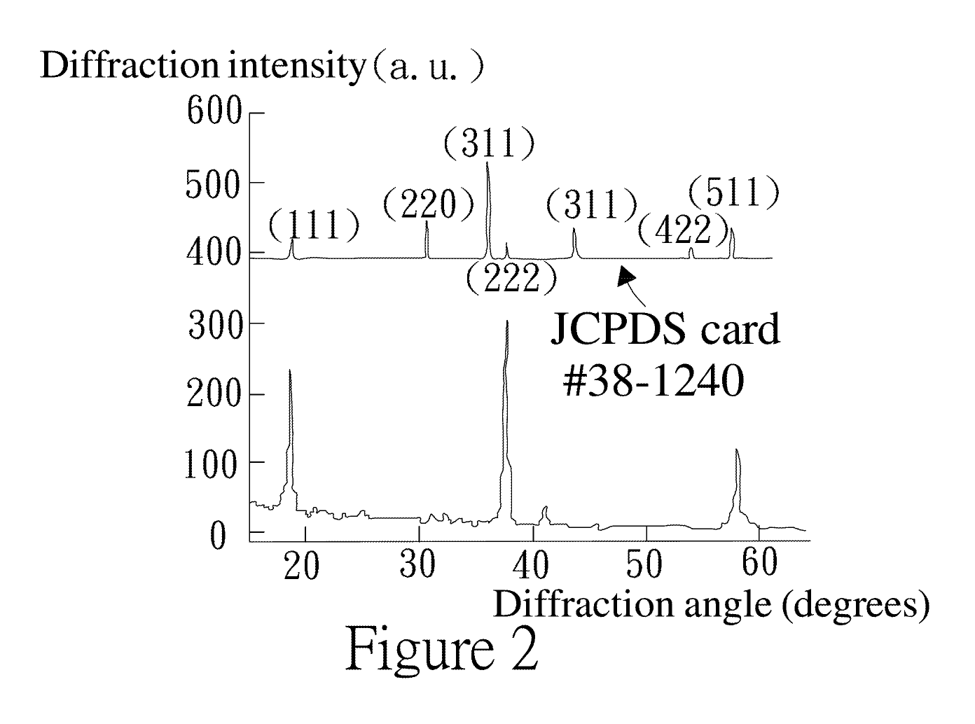

Please refer to FIG. 2, which shows a schematic diagram of the lattice according to an embodiment of the present invention. As shown in the figure, the present invention provides a solar-blind sensing device 10 with a doping structure. The oxide epitaxial sensing layer 14 uses gallium oxide (Ga₂O₃) and zinc oxide (ZnO) to form zinc gallium oxide (ZnGa₂O₄, ZGO), which is a semiconductor material with a wide bandgap of 5 eV. According to the present embodiment, the high breakdown voltage and high saturated drift velocity of electrons of zinc gallium oxide give the sensing device superior optoelectronic properties. The 2θ of zinc gallium oxide has peak values at 18.67, 37.77, and 58.17 degrees. In other words, when the incident angles of X-ray diffraction are 18.67, 37.77, and 58.17 degrees, X-ray diffraction spectrum responses occur. The incident angles are close to those of a standard lattice diagram at 18.4 degree (111), 37.34 degree (222), and 57.4 degree (511) in the card number 38-1240 of the Joint Committee on Powder Diffraction Standards (JCPDS).

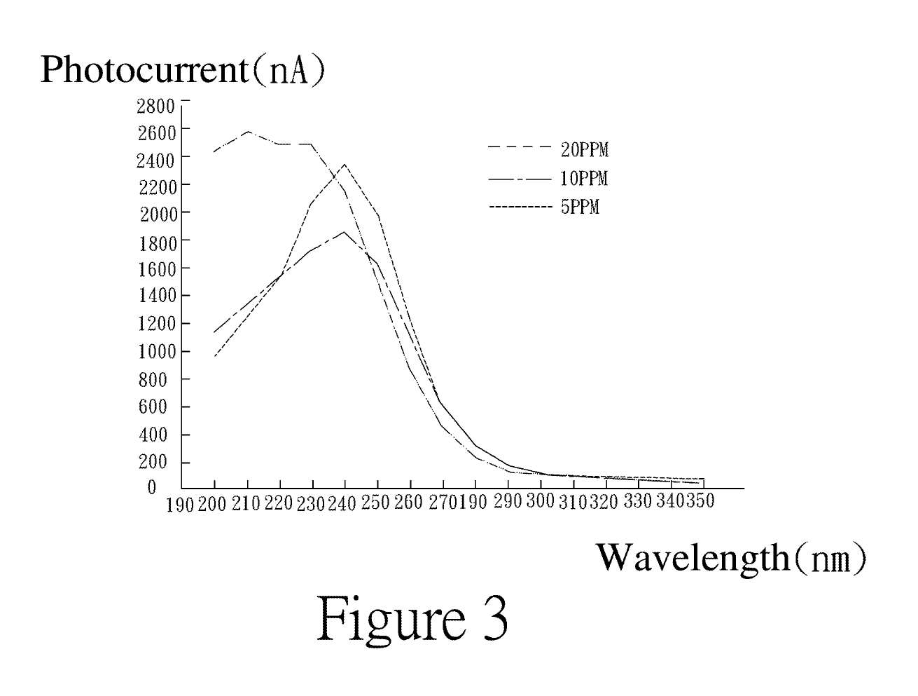

Furthermore, because the substrate 12 is a sapphire substrate, it is beneficial for gallium oxide epitaxy. As shown in FIG. 2, metal-organic chemical vapor deposition (MOCVD) is adopted for doping zinc uniformly in the epitaxial structure of gallium oxide and forming a single-crystalline thin film. In addition, as shown in FIG. 3, which shows curves of photocurrents versus wavelengths according to an embodiment of the present invention. The gallium oxide according to the present embodiment is doped with zinc. The response of illuminating by ultraviolet light with wavelengths between 150 and 300 nanometers on the oxide epitaxial sensing layer 14 grown at 5, 10, and 20 sccm of zinc-containing gas is decent. Namely, the oxide epitaxial sensing layer 14 can generate photocurrents at nanoampere level under the stimulation of ultraviolet light.

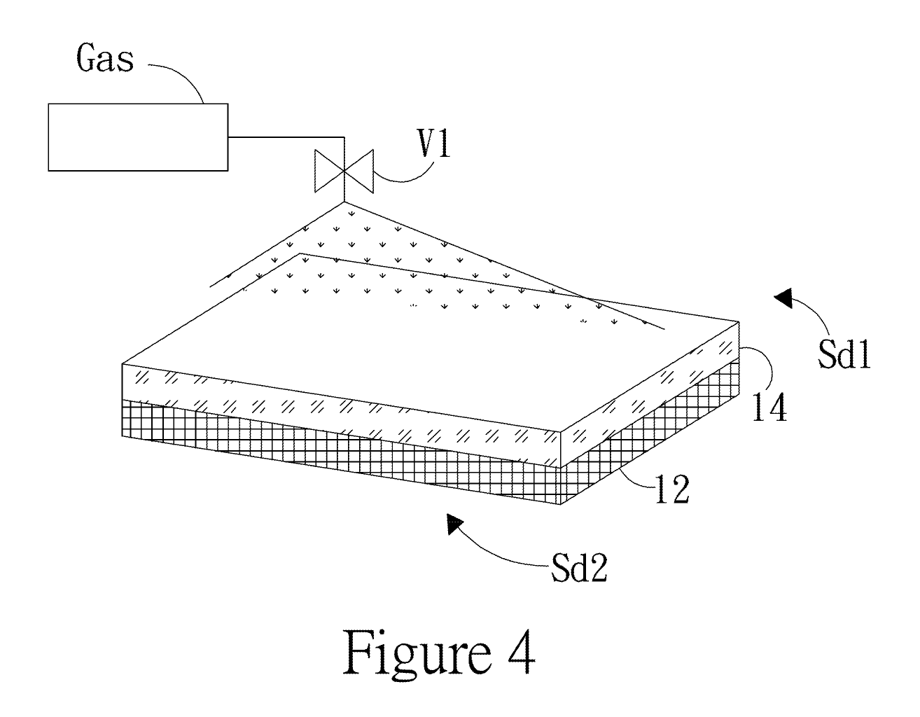

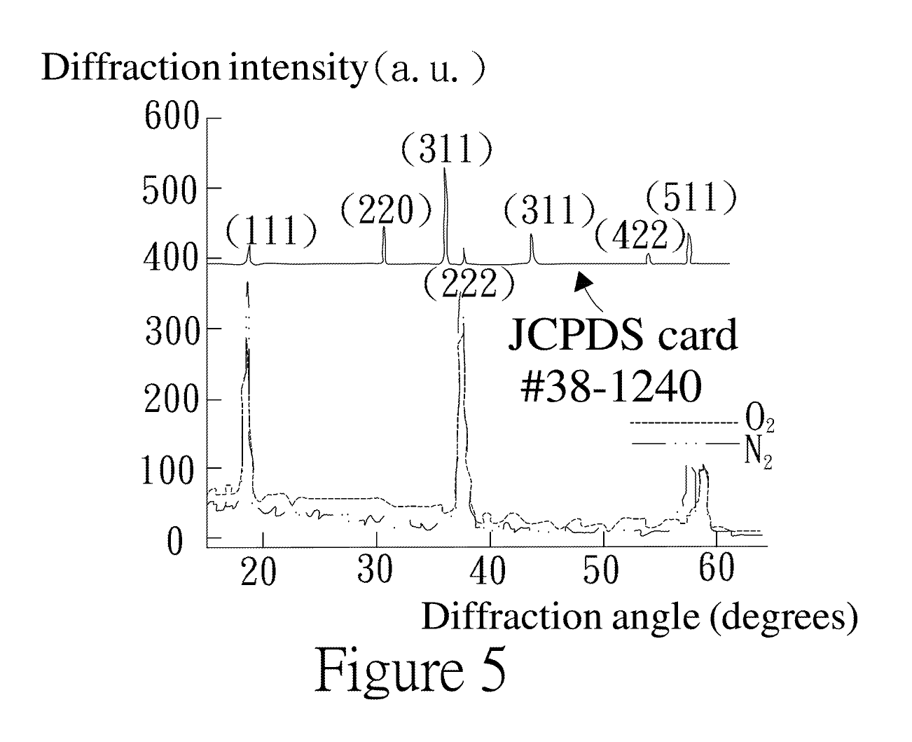

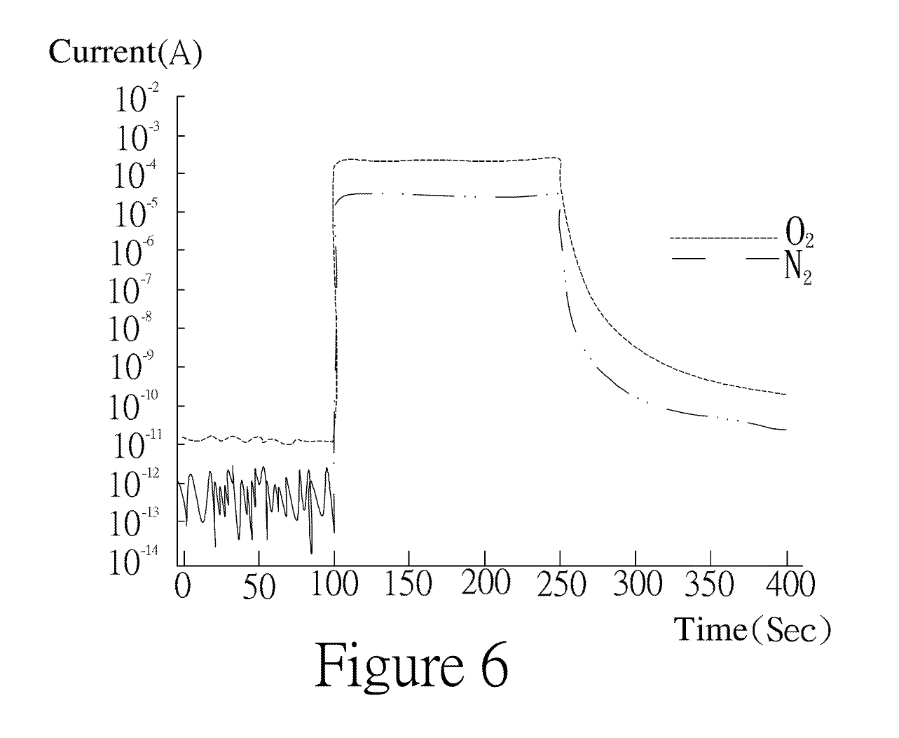

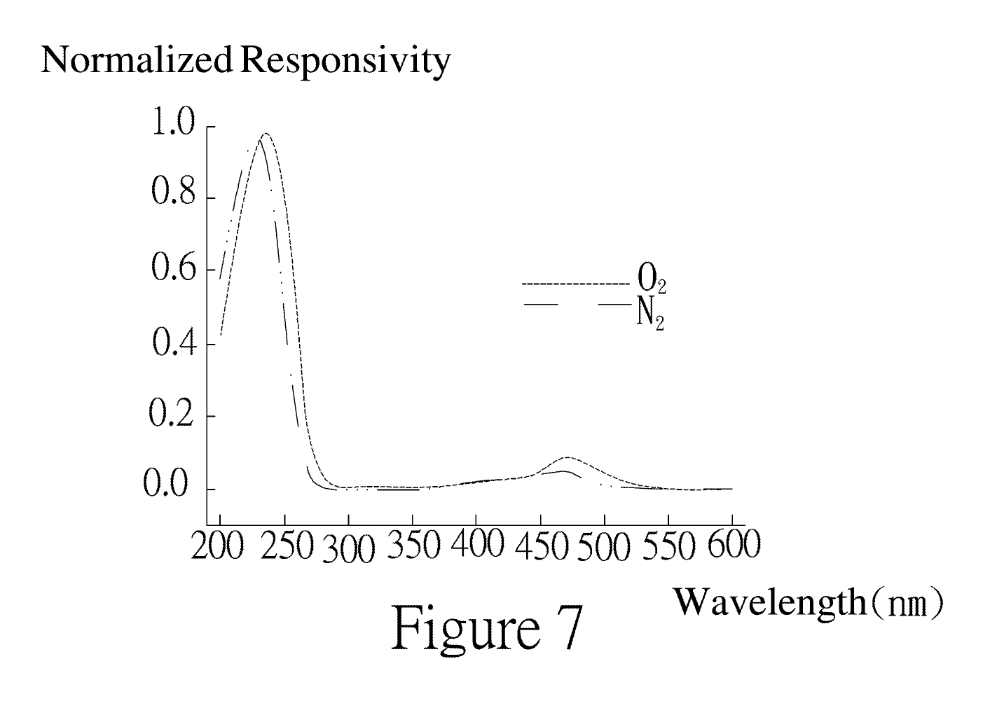

Please refer to FIG. 4, which shows a schematic diagram of annealing according to another embodiment of the present invention. As shown in the figure, after the oxide epitaxial sensing layer 14 is formed on the substrate 12, perform an annealing process, such as microwave annealing or laser annealing, on the oxide epitaxial sensing layer 14. Use the gas in a gas container Gas and a valve V1 to aerate the epitaxy chamber (not shown in the figure) for annealing the oxide epitaxial sensing layer 14 at 800 to 950 degrees Celsius. The gas in the gas container Gas can be nitrogen or oxygen. As shown in FIG. 5, which shows a schematic diagram of the lattice according to another embodiment of the present invention. After the oxide epitaxial sensing layer 14 is annealed at 800 degrees Celsius, the lattice strength is better than the lattice strength in FIG. 2. As shown in FIG. 6, after gallium oxide is annealed at 800 degrees Celsius in oxygen or nitrogen, the sensing wavelength of the solar-blind sensing device 10 is located between 150 and 280 nm, or even between 200 and 250 nm. As shown in FIG. 7, oxygen or nitrogen is used for annealing the oxide epitaxial sensing layer 14. According to the present embodiment, while annealing at around 800 to 950 degrees Celsius in, particularly, oxygen ambient, the reaction time will be shortened.

To sum up, the present invention provides a solar-blind sensing device with a doping structure. It uses a wide-bandgap oxide to fabricate the sensing layer for improving the sensing intensity of the solar-blind sensing device. In addition, by using an annealing process, the present invention can sense shorter wavelengths and provide superior sensing performance.

1. A solar-blind sensing device with a wide-bandgap oxide, comprising:
a substrate;
an oxide epitaxial sensing layer, disposed on said substrate, and formed by the elements including oxygen, gallium, and zinc; and
a circuit layer, disposed on said oxide epitaxial sensing layer, including a first circuit unit and a second circuit unit, said first circuit unit located on a first side of said circuit layer; said second circuit unit located on a second side of said circuit layer; said first circuit unit including a plurality of first extending parts; said second circuit unit including a plurality of second extending parts; and said plurality of first extending parts and said plurality of second extending parts interlaced and extending on said oxide epitaxial sensing layer;
where a ray of incident light is incident to said oxide epitaxial sensing layer, said oxide epitaxial sensing layer generates a photocurrent between said first circuit unit and said second circuit unit, said photocurrent is led to the exterior via said circuit layer, and a flow rate of said zinc is 5 to 20 sccm.

2. The solar-blind sensing device of claim 1, wherein said oxide epitaxial sensing layer is a single-crystalline thin film.

3. The solar-blind sensing device of claim 1, wherein a continuously extending snake-shaped groove is located between said plurality of first extending parts and said plurality of second extending parts.

4. The solar-blind sensing device of claim 1, wherein the material of said oxide epitaxial sensing layer is zinc gallium oxide (ZnGa₂O₄, ZGO).

5. (canceled)

6. The solar-blind sensing device of claim 1, wherein the incident angles of X-ray diffraction to said oxide epitaxial sensing layer include 18.67, 37.77, and 58.17 degrees.

7. The solar-blind sensing device of claim 1, wherein said substrate is a sapphire substrate.

8. The solar-blind sensing device of claim 1, wherein said oxide epitaxial sensing layer is annealed at 800 to 950 degrees Celsius in nitrogen or oxygen ambient.

9. The solar-blind sensing device of claim 1, wherein the sensing wavelength of said oxide epitaxial sensing layer is between 150 and 280 nanometers.
